(19) United States
(12) Patent Application Publication
(10) Pub. No.: US 2026/0362853 A1
(43) Pub. Date: Nov. 12, 2026

(54) EPITAXIAL STRUCTURE OF LONG-WAVELENGTH InGaN-BASED LIGHT-EMITTING DIODE AND PREPARATION METHOD THEREOF

(71) Applicant: PEKING UNIVERSITY, Beijing (CN)

(72) Inventors: Zhizhong CHEN, Beijing (CN); Zuojian PAN, Beijing (CN); Haodong ZHANG, Beijing (CN); Ling Hu, Beijing (CN); Fei HUANG, Beijing (CN); Chuhan DENG, Beijing (CN); Yian CHEN, Beijing (CN); Boyan DONG, Beijing (CN); Daqi WANG, Beijing (CN); Yuchen LI, Beijing (CN); Weihua CHEN, Beijing (CN); Fei JIAO, Beijing (CN); Xiangning KANG, Beijing (CN); Bo SHEN, Beijing (CN)

(21) Appl. No.: 19/115,546

(22) PCT Filed: Mar. 14, 2024
(86) PCT No.: PCT/CN2024/081556

§ 371 Date: Mar. 26, 2025

(30) Foreign Application Priority Data
Dec. 15, 2023 (CN) 202311727409.9

(51) Int. Cl. H10H 20/812; H10H 20/01; H10H 20/825

(52) U.S. Cl. CPC H10H 20/812; H10H 20/0137; H10H 20/825

(57) ABSTRACT

Disclosed are an epitaxial structure of an InGaN-based light-emitting diode and a preparation method thereof. The epitaxial structure includes a substrate, an unintentionally doped gallium nitride layer, an n-type doped gallium nitride layer, a multiple-quantum well with trench defects, a repairment layer, a light-emitting multiple-quantum well, and a p-type doped gallium nitride layer; wherein the multiple-quantum well with trench defects is made of InₓGa₁₋ₓN/GaN, where x is an indium component in the multiple-quantum well with trench defects; the repairment layer is configured as a hole blocking layer; and the light-emitting multiple-quantum well is made of In_{z}Ga_{1-z}N/GaN, where z is an indium component in the light-emitting multiple-quantum well; and the indium component z in the light-emitting multiple-quantum well is greater than the indium component x in the multiple-quantum well with trench defects.

### CROSS REFERENCE TO RELATED APPLICATION

This application is a national stage application of International Patent Application No. PCT/CN2024/081556, filed on Mar. 14, 2024, which claims priority to Chinese Patent Application No. CN202311727409.9, filed with the China National Intellectual Property Administration on Dec. 15, 2023 and entitled “EPITAXIAL STRUCTURE OF LONG-WAVELENGTH InGaN-BASED LIGHT-EMITTING DIODE AND PREPARATION METHOD THEREOF”. The disclosure of the two applications is incorporated by references herein in their entireties as part of the present application.

### TECHNICAL FIELD

The present disclosure relates to the field of semiconductor devices, and specifically to an epitaxial structure of a long-wavelength InGaN-based light-emitting diode and a preparation method thereof.

### BACKGROUND

High-efficiency InGaN-based light-emitting diodes (LED) play an important role in lighting, display, visible light communication, and biological health. Currently, full-color display based on InGaN-based LEDs is an important demand in the field of new displays. However, blue and green InGaN-based LEDs are relatively efficient, but red InGaN-based LEDs are still at a relatively low-efficiency level.

There are two main reasons for the low efficiency of red InGaN LEDs. One reason is that the growth temperature of a red light quantum well is low. For red InGaN LEDs with a high indium component, the growth temperature of a quantum well is generally below 700 °C when metalorganic vapor phase epitaxy (MOVPE) is used to maintain the incorporation of In. However, a multiple-quantum well grown at a low temperature often contains high-density defects, which significantly reduces the radiative recombination efficiency of red InGaN-based LEDs. Another aspect is the excessive compressive stress introduced by lattice mismatch in the red light quantum well. The compressive stress would induce a strongly polarized electric field in the InGaN quantum well layer, resulting in a Quantum-Confined Stark Effect. Meanwhile, according to the principle of minimum energy, when the strain energy required for In—N bonding is large, compressive strain would suppress the incorporation of indium.

Due to the defect shielding and stress relief effects of the V-pit structure, V-pits in the multiple-quantum well can be used to solve problems in the red light quantum well, such as defects, polarized electric fields and indium incorporation. In the InGaN/GaN multiple-quantum well, V-pits have two main sources: one is a single V-pit structure induced by threading dislocation, and the other is a circular V-pit structure, i.e., a trench structure, induced by stacking fault in the quantum barrier. In the past, the single V-pit structure induced by threading dislocation has been used effectively to improve the luminous efficiency of red InGaN LEDs (Photon. Res. 7, 144-148 (2019); Photon. Res. 8, 1671-1675 (2020)). However, the trench structure induced by stacking fault has been considered a defect structure that severely reduces the luminous efficiency of InGaN LEDs.

In previous studies, the trench structure significantly reduces the overall luminous efficiency of blue and green InGaN LEDs (Appl. Phys. Lett. 105, 112110(2014)). However, local luminescence enhancement and wavelength redshift phenomena are observed in quantum wells inside part of the trench structure (Appl. Phys. Lett. 98, 141908(2011)). The local-area intensity enhancement is mainly due to the defect shielding and stress relaxation effect within the trench structure, and the wavelength redshift is due to increased indium incorporation (Nanoscale, 14, 402 (2022)). Therefore, the trench structure has the potential to increase the efficiency of red InGaN LEDs. However, there is still a lack of reasonable control methods for utilizing the defect shielding and stress relaxation effects of the trench structure to improve the overall luminous efficiency of red InGaN LEDs.

### SUMMARY

In view of the above problems of conventional technology, the present disclosure proposes an epitaxial structure of a long-wavelength InGaN-based light-emitting diode and a preparation method thereof. By introducing trenches in a quantum well and using the luminescence enhancement and wavelength redshift effect of the trenches on the quantum well, an epitaxial structure of a high-efficiency long-wavelength InGaN-based light-emitting diode is prepared.

An object of the present disclosure is to propose an epitaxial structure of a long-wavelength InGaN-based light-emitting diode.

The epitaxial structure of the long-wavelength InGaN-based light-emitting diode according to the present disclosure includes a substrate, an unintentionally doped gallium nitride layer, an n-type doped gallium nitride layer, a multiple-quantum well with trench defects, a repairment layer, a light-emitting multiple-quantum well, and a p-type doped gallium nitride layer.

In some embodiments, the epitaxial structure is prepared by a process comprising the following steps:
forming the unintentionally doped gallium nitride layer and the n-type doped gallium nitride layer sequentially on the substrate;
epitaxially growing the multiple-quantum well with trench defects on the n-type doped gallium nitride layer, during which high-density trenches are formed simultaneously on a surface of a multiple-quantum well by controlling growth conditions, wherein the multiple-quantum well with trench defects is made of InₓGa₁₋ₓN/GaN, where x is an indium component in the multiple-quantum well with trench defects, and trenches of the multiple-quantum well with trench defects are configured as spatial isolation to prevent carriers in the quantum well inside the trenches being affected by external defects;
forming the repairment layer on the multiple-quantum well with trench defects, wherein the repairment layer is configured for repairing a rough surface of the multiple-quantum well with trench defects to provide a flat growth surface for subsequent growth of a light-emitting multiple-quantum well, and the repairment layer is configured as a hole blocking layer to block holes from the p-type doped gallium nitride layer from entering the multiple-quantum well with trench defects, such that the holes are concentrated in the light-emitting multiple-quantum well for radiative recombination;
epitaxially growing the light-emitting multiple-quantum well on the repairment layer, wherein the light-emitting multiple-quantum well is configured as a light-emitting quantum well upon current injection for emitting light of a long set wavelength, and the light-emitting multiple-quantum well is made of In_{z}Ga_{1-z}N/GaN, where z is an indium component in the light-emitting multiple-quantum well, and the indium component z in the light-emitting multiple-quantum well is greater than the indium component x in the multiple-quantum well with trench defects; the trenches in the multiple-quantum well with trench defects provide stress relaxation for the repairment layer such that a lattice of the repairment layer is expanded, thereby increasing incorporation of indium in the light-emitting multiple-quantum well; and an increase in indium incorporated in the light-emitting multiple-quantum well reduces band gaps of well layers of the light-emitting multiple-quantum well, thereby achieving long-wavelength light emission; and
forming the p-type doped gallium nitride layer on the light-emitting multiple-quantum well, thus obtaining the epitaxial structure of the long-wavelength InGaN-based light-emitting diode.

In some embodiments, the substrate is made of sapphire (Al₂O₃), silicon (Si), or silicon carbide (SiC).

In some embodiments, the unintentionally doped gallium nitride layer has a thickness of 1 μm to 5 μm, and the n-type doped gallium nitride layer has a thickness of 1 μm to 10 μm; and the n-type doped gallium nitride layer has a doping concentration of 1×10¹⁸ cm⁻³ to 1×10²⁰ cm⁻³.

In some embodiments, the indium component in InₓGa₁₋ₓN in the multiple-quantum well with trench defects satisfies 0.1≤x≤0.4. In some embodiments, a density of trenches formed on the surface of the multiple-quantum well is between 1×10⁷ cm⁻² and 1×10¹⁰ cm⁻²; and a single trench has a lateral dimension of 10 nm to 1 μm and a depth of 10 nm to 300 nm.

In some embodiments, the repairment layer has a thickness of less than 500 nm; and the repairment layer is made of a thick In_{y}Ga_{1-y}N film, a In_{y}Ga_{1-y}N/GaN superlattice, or a gallium nitride layer, where y is an indium component in In_{y}Ga_{1-y}N in the repairment layer, 0.01≤y≤0.2, and the indium component in the repairment layer is lower than the indium component in the multiple-quantum well with trench defects.

In some embodiments, the indium component in In_{z}Ga_{1-z}N in the light-emitting multiple-quantum well satisfies 0.2≤z≤0.5, and the indium component in the light-emitting multiple-quantum well is higher than the indium component in the multiple-quantum well with trench defects.

Another object of the present disclosure is to propose a method for preparing the epitaxial structure of a long-wavelength InGaN-based light-emitting diode.

The method for preparing the epitaxial structure of the long-wavelength InGaN-based light-emitting diode according to the present disclosure includes the following steps:
1) providing the substrate that is usable of growing gallium nitride;
2) epitaxially growing the unintentionally doped gallium nitride layer and the n-type doped gallium nitride layer sequentially on the substrate;
3) epitaxially growing the multiple-quantum well with trench defects on the n-type doped gallium nitride layer, during which high-density trenches are formed simultaneously on a surface of a multiple-quantum well by controlling growth conditions, wherein the growth conditions for generating high-density trenches are lowering growth temperatures of the well layers and/or barrier layers, using trimethylgallium (TMGa) as a metal source, reducing a flow ratio of ammonia (NH₃) to the metal source, or improving a flow ratio of trimethylindium (TMIn) to triethylgallium (TEGa); the multiple-quantum well with trench defects is made of InₓGa₁₋ₓN/GaN, where x is the indium component in the multiple-quantum well with trench defects; the multiple-quantum well with trench defects includes a plurality of well layers and barrier layers that alternate with each other, wherein the well layers each are made of InₓGa₁₋ₓN, where x is the indium component in the multiple-quantum well with trench defects, and the barrier layers each are made of GaN; and the trenches of the multiple-quantum well with trench defects is configured as spatial isolation to avoid carriers in the quantum well inside the trenches being affected by external defects;
4) epitaxially growing the repairment layer on the multiple-quantum well with trench defects, with a growth temperature of the repairment layer being higher than a growth temperature of the multiple-quantum well with trench defects, wherein the repairment layer is used for repairing a rough surface of the multiple-quantum well with trench defects to provide a flat growth surface for subsequent growth of a light-emitting multiple-quantum well, and the repairment layer is configured as a hole blocking layer to block holes from the p-type doped gallium nitride layer from entering the multiple-quantum well with trench defects, such that the holes are concentrated in the light-emitting multiple-quantum well for radiative recombination;
5) epitaxially growing the light-emitting multiple-quantum well on the repairment layer, during which the formation of an unintentionally introduced trench is avoided by controlling growth conditions, wherein the light-emitting multiple-quantum well is configured as a light emitting layer upon current injection for emitting a long-wavelength light; well layers of the light-emitting multiple-quantum well each are made of In_{z}Ga_{1-z}N, where z is the indium component in the light-emitting multiple-quantum well; the light-emitting multiple-quantum well includes a plurality of well layers and barrier layers that alternate with each other, wherein the well layers each are made of In_{z}Ga_{1-z}N, where z is the indium component in the light-emitting multiple-quantum well, and the barrier layers each are made of GaN; and the indium component z in the light-emitting multiple-quantum well is greater than the indium component x in the multiple-quantum well with trench defects; the trenches in the light-emitting multiple-quantum well provide stress relaxation for the repairment layer such that the lattice of the repairment layer is expanded, thereby increasing the incorporation of indium in the light-emitting multiple-quantum well; and increased incorporation of indium in the light-emitting multiple-quantum well reduces band gaps of well layers of the light-emitting multiple-quantum well, thereby achieving long-wavelength light emission; and
6) growing the p-type doped gallium nitride layer on the light-emitting multiple-quantum well, thus obtaining the epitaxial structure of the long-wavelength InGaN-based light-emitting diode.

In some embodiments, in step 1), the substrate is made of sapphire (Al₂O₃), silicon (Si), or silicon carbide (SiC).

In some embodiments, in step 2), the unintentionally doped gallium nitride layer has a thickness of 1 μm to 5 μm, and the n-type doped gallium nitride layer has a thickness of 1 μm to 10 μm; and the n-type doped gallium nitride layer has a doping concentration of 1×10¹⁸ cm⁻³ to 1×10²⁰ cm⁻³.

In some embodiments, in step 3), the indium component x in the multiple-quantum well with trench defects satisfies 0.1≤x≤0.4. In some embodiments, a density of the trenches formed on the surface of the multiple-quantum well is between 1×10⁷ cm⁻² and 1×10¹⁰ cm⁻²; a single trench has a lateral dimension of 10 nm to 1 μm and a depth of 10 nm to 300 nm; and the growth conditions for generating the trenches are: growing the well layers at a temperature of 500 °C to 750 °C and the barrier layers at a temperature of 600 °C to 850 °C, a flow ratio of trimethylindium (TMIn) to triethylgallium (TEGa) being in a range of 5-50, or a flow ratio of ammonia (NH₃) to the metal source being in a range of 50-500.

In some embodiments, in step 4), the repairment layer has a thickness of less than 500 nm; and the repairment layer is made of a thick In_{y}Ga_{1-y}N film, a In_{y}Ga_{1-y}N/GaN superlattice, or a gallium nitride layer, where y is an indium component in In_{y}Ga_{1-y}N in the repairment layer, and 0.01≤y≤0.2; and a growth temperature of the repairment layer is in a range of 750 °C to 1000 °C.

In some embodiments, in step 5), the indium component z in the light-emitting multiple-quantum well satisfies 0.2≤z≤0.5, wherein for the light-emitting multiple-quantum well, growth temperatures of the well layers each are in a range of 600 °C to 750 °C, growth temperatures of the barrier layers is in a range of 700 °C to 900 °C, triethylgallium is used as a metal source, and a flow ratio of trimethylindium (TMIn) to triethylgallium (TEGa) is in a range of 1-20.

Advantages of some embodiments of the present disclosure are as follows:
(1) the trenches in the multiple-quantum well with trench defects provide stress relaxation for the repairment layer such that the lattice of the repairment layer is expanded, which is beneficial to increasing the incorporation of indium in the light-emitting multiple-quantum well;
(2) the trenches in the multiple-quantum well with trench defects are configured as spatial isolation to avoid the carriers in the quantum well inside the trenches being affected by external defects;
(3) the rough surface of the multiple-quantum well with trench defects grown at a low temperature is repaired by the repairment layer, thus providing a flat growth surface for the subsequent growth of the light-emitting multiple-quantum well; and
the repairment layer is configured as a hole blocking layer to block holes from the p-type doped gallium nitride layer from entering the multiple-quantum well with trench defects, such that the holes are concentrated in the light-emitting multiple-quantum well for radiative recombination.

### BRIEF DESCRIPTION OF THE DRAWINGS

FIG. 1 shows a structure block diagram of an epitaxial structure of a long-wavelength InGaN-based light-emitting diode of the present disclosure.

FIG. 2 shows a sectional view of an example of an epitaxial structure of a long-wavelength InGaN-based light-emitting diode of the present disclosure.

FIG. 3 shows a scanning electron microscope image of a surface of the multiple-quantum well with trench defects in an example of an epitaxial structure of a long-wavelength InGaN-based light-emitting diode of the present disclosure.

FIG. 4 shows a schematic diagram of trenches in the multiple-quantum well with trench defects in an example of an epitaxial structure of a long-wavelength InGaN-based light-emitting diode of the present disclosure.

FIG. 5 shows a scanning electron microscope image of a surface of the repairment layer in an example of an epitaxial structure of a long-wavelength InGaN-based light-emitting diode of the present disclosure.

FIG. 6 shows a fluorescence spectrogram of an example of an epitaxial structure of a long-wavelength InGaN-based light-emitting diode of the present disclosure under the irradiation of 405 nm laser.

### DETAILED DESCRIPTION OF THE EMBODIMENTS

The present disclosure will be further elaborated below through specific examples in conjunction with the accompany drawings.

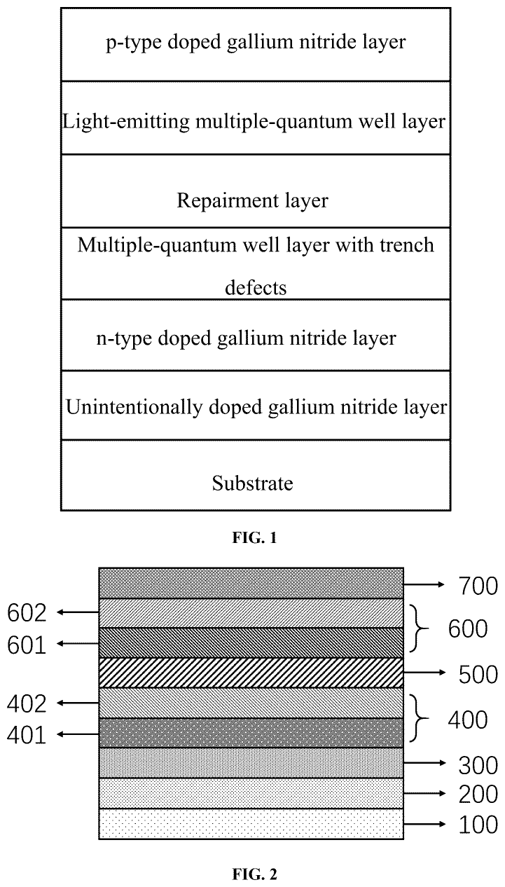

In this example, as shown in FIGS. 1 and 2, a method for preparing an epitaxial structure of a long-wavelength InGaN-based light-emitting diode was performed as follows:

1) A sapphire as a substrate 100 was provided.

2) The substrate 100 was placed in a MOCVD reaction chamber, and heated to 1050 °C in H₂ atmosphere, followed by purging for 10 minutes and then cooling to 540 °C. TMGa, NH₃ and H₂ were then introduced therein, to grow a nucleation layer. The system was heated to 1040 °C, and a non-doped gallium nitride layer 200 with a thickness of 2 microns was grown thereon.

TMGa, NH₃, SiH₄, and H₂ were then introduced therein, and at 1060 °C, an n-type doped gallium nitride layer 300 with a thickness of 1.5 microns was grown on the non-doped gallium nitride layer 200.

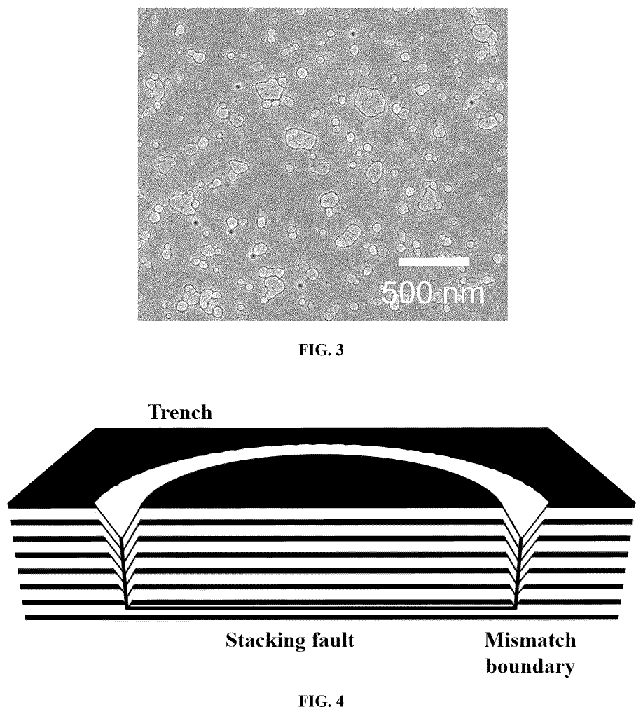

3) The system was cooled to 690 °C, and TEGa, NH₃, SiH₄, and N₂ were introduced therein, and a cyclical multiple-quantum well with trench defects was grown. The multiple-quantum well with trench defects in this example was an 8-cycle green light quantum well 400, and each cycle consisted of an InGaN green light quantum well layer 401 and a trench-type GaN barrier layer 402, wherein the InGaN green light quantum well layer 401 was grown at 630 °C, with the introduction of TEGa, TMIn, NH₃, and N₂, a growth thickness of 2.5 nm, and an indium component being about 25%; the trench-type GaN barrier layer 402 was grown at 690 °C, with the introduction of TEGa, NH₃, and N₂, and a thickness of 10 nm. The scanning electron microscope image of the surface of the multiple-quantum well with trench defects is shown in FIG. 3, and since the growth temperature is low, trenches with a density of about 5×10⁹ cm⁻² can be observed on the surface of the green light quantum well. As shown in the schematic diagram of the trenches in FIG. 4, the trenches in the multiple-quantum well with trench defects are configured as spatial isolation to avoid the carriers in the quantum well inside the trenches being affected by external defects.

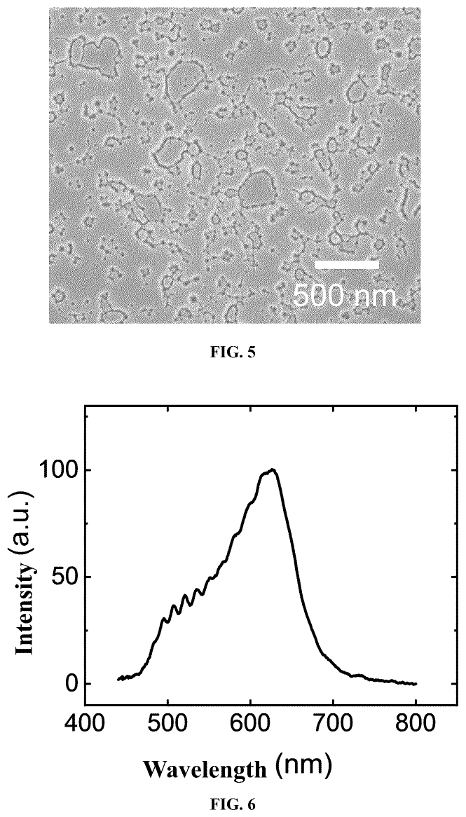

4) A thick n-type doped In_{0.05}Ga_{0.95}N film was epitaxially grown on the multiple-quantum well with trench defects as a repairment layer 500 according to the following procedures: the temperature was raised to 790 °C, and TEGa, TMIn, NH₃, SiH₄, and N₂ were then introduced, thereby growing a thick n-type doped In_{0.05}Ga_{0.95}N film with a thickness of 80 nm. The flatness of the surface was improved because the growth temperature was higher than that of the previous green light quantum well. Also, the n-type doped In_{0.05}Ga_{0.95}N repairment layer 500 was configured as a hole blocking layer to prevent holes from entering the green light quantum well under electric injection conditions. In addition, as shown in FIG. 5, due to the presence of high-density trenches in the green light quantum well, the compressive stress on the repairment layer 500 was reduced, resulting in the expansion of the lattice of the repairment layer itself, which facilitated the subsequent incorporation of indium into the quantum well.

5) A light-emitting multiple-quantum well was epitaxially grown on the repairment layer. The light-emitting multiple-quantum well in this example was a 3-cycle red light quantum well 600, and each cycle consisted of an InGaN red light quantum well layer 601 and a red light GaN barrier layer 602. The InGaN red light quantum well layer 601 was grown at 665 °C, with the introduction of TEGa, TMIn, NH₃, and N₂, a growth thickness of 2.5 nm, and an indium component of about 40%. The red light GaN barrier layer 602 was grown at 770 °C, with the introduction of TEGa, NH₃, and N₂, and a thickness of 10 nm. The light-emitting multiple-quantum well was configured as a light-emitting layer upon current injection, and both the light-emitting multiple-quantum well and the multiple-quantum well with trench defects acted as light-emitting layers upon laser excitation.

The trenches in the multiple-quantum well with trench defects provided stress relaxation for the repairment layer, such that the lattice of the repairment layer was expanded, thereby increasing the incorporation of indium in the light-emitting multiple-quantum well; and increased incorporation of indium achieves long-wavelength light emission.

6) A p-type doped gallium nitride layer 700 was grown on the light-emitting multiple-quantum well by introducing TMGa, NH₃, Cp₂Mg, and H₂, and growing at 920 °C to a thickness of about 150 nm, so as to obtain the epitaxial structure of the long-wavelength InGaN-based light-emitting diode.

After completing the whole epitaxial structure of a long-wavelength InGaN-based light-emitting diode above, an epitaxial wafer with a light-emitting wavelength in the red band was obtained. FIG. 6 shows a fluorescence spectrum of the red light epitaxial wafer under the irradiation of 405 nm laser. As can be seen from FIG. 6, the emission spectrum includes green light with a peak wavelength of about 525 nm and red light with a peak wavelength of about 625 nm, where the emission of green light is sourced from the emission of the multiple-quantum well with trench defects, and the emission of red light is sourced from the emission of the light-emitting quantum well. Since the multiple-quantum well with trench defects is grown at a low temperature, the defect density inside the quantum well is high, such as stacking fault or misfit dislocations. Due to the influence of defects, the intensity of green light thereof is weak. In the case of current injection, due to the weak mobility of holes, the underlying green light quantum well does not participate in luminescence. However, high-density trenches are introduced into the green light quantum well at a low temperature, which helps improve the subsequent luminescence of the red light quantum well, as shown in FIG. 4.

Although high-density trenches are introduced into the green light quantum well grown at a low temperature, the low temperature leads to surface roughening and poor crystal quality thereof, making it difficult to provide a flat surface with high-quality crystals for the growth of red light quantum well. Therefore, after introducing trenches into the green light quantum well, it is particularly important to grow a repairment layer. In this example, the growth temperature of the repairment layer of a thick InGaN film is 100 °C or more higher than that of the green light quantum well, with higher surface flatness and relatively good crystal quality, thus providing a good growth surface for the red light quantum well. Moreover, trenches could be remained in the repairment layer, as shown in FIG. 5, and on the surface of the repairment layer, there are trenches with a density of about 2×10⁹ cm⁻². In addition, due to the presence of high-density trenches, the compressive stress on the repairment layer of a thick InGaN film itself partially relaxes and the lattice is expanded, which facilitates the subsequent incorporation of indium into the red light quantum well. Therefore, the main functions of the repairment layer of a thick InGaN film in this example are: (1) repairing the rough surface of the green light quantum well; (2) retaining high-density trenches; and (3) the self-stress being relaxed, and playing a role in expanding the lattice. In the subsequent red light quantum well, the high-density trenches could provide a defect shielding effect and make the incorporation of indium more efficient, thus providing a new approach for achieving high-efficiency red light InGaN LEDs.

Finally, it should be noted that the disclosed examples are intended to assist in further understanding of the present disclosure, but those skilled in the art appreciates that various substitutions and modifications are possible without departing from the spirit and scope of the present disclosure and the appended claims. Therefore, the present disclosure should not be limited to the content disclosed in the examples, and the scope of protection claimed by the present disclosure is subject to the scope defined by the claims.

1. An epitaxial structure of an InGaN-based light-emitting diode, wherein the epitaxial structure comprises a substrate, an unintentionally doped gallium nitride layer, an n-type doped gallium nitride layer, a multiple-quantum well with trench defects, a repairment layer, a light-emitting multiple-quantum well, and a p-type doped gallium nitride layer; wherein
the multiple-quantum well with trench defects is made of InₓGa₁₋ₓN/GaN, where x is an indium component in the multiple-quantum well with trench defects;
the repairment layer is configured as a hole blocking layer; and
the light-emitting multiple-quantum well is made of In_{z}Ga_{1-z}N/GaN, where z is an indium component in the light-emitting multiple-quantum well; and the indium component z in the light-emitting multiple-quantum well is greater than the indium component x in the multiple-quantum well with trench defects.

2. The epitaxial structure of claim 1, wherein the epitaxial structure is prepared by a process comprising:
forming the unintentionally doped gallium nitride layer and the n-type doped gallium nitride layer sequentially on the substrate;
epitaxially growing the multiple-quantum well with trench defects on the n-type doped gallium nitride layer, during which high-density trenches are simultaneously formed on a surface of a multiple-quantum well by controlling growth conditions, wherein the multiple-quantum well with trench defects is made of InₓGa₁₋ₓN/GaN, where x is the indium component in the multiple-quantum well with trench defects;
forming the repairment layer on the multiple-quantum well with trench defects;
epitaxially growing the light-emitting multiple-quantum well on the repairment layer, wherein the light-emitting multiple-quantum well is made of In_{z}Ga_{1-z}N/GaN, where z is the indium component in the light-emitting multiple-quantum well; and the indium component z in the light-emitting multiple-quantum well is greater than the indium component x in the multiple-quantum well with trench defects; and
forming the p-type doped gallium nitride layer on the light-emitting multiple-quantum well, thereby obtaining the epitaxial structure of the InGaN-based light-emitting diode.

3. The epitaxial structure of claim 1, wherein the unintentionally doped gallium nitride layer has a thickness of 1 μm to 5 μm, and the n-type doped gallium nitride layer has a thickness of 1 μm to 10 μm; and
the n-type doped gallium nitride layer has a doping concentration of 1×10¹⁸ cm⁻³ to 1×10²⁰ cm⁻³.

4. The epitaxial structure of claim 1, wherein the indium component in InₓGa₁₋ₓN in the multiple-quantum well with trench defects satisfies 0.1≤x≤0.4;
a density of trenches formed on a surface of the multiple-quantum well is between 1×10⁷ cm⁻² and 1×10¹⁰ cm⁻²; and
a single trench has a lateral dimension of 10 nm to 1 μm and a depth of 10 nm to 300 nm.

5. The epitaxial structure of claim 1, wherein the multiple-quantum well with trench defects comprises a plurality of well layers and barrier layers that alternate with each other;
the well layers each are made of InₓGa₁₋ₓN, where x is the indium component in the multiple-quantum well with trench defects; and
the barrier layers each are made of GaN.

6. The epitaxial structure of claim 1, wherein the repairment layer has a thickness of less than 500 nm; and
the repairment layer is made of a In_{y}Ga_{1-y}N film, a In_{y}Ga_{1-y}N/GaN superlattice, or a gallium nitride layer, where y is an indium component in In_{y}Ga_{1-y}N in the repairment layer, and satisfies 0.01≤y≤0.2, and the indium component in the repairment layer is lower than the indium component in the multiple-quantum well with trench defects.

7. The epitaxial structure of claim 1, wherein the indium component z in the light-emitting multiple-quantum well satisfies 0.2≤z≤0.5, and the indium component in the light-emitting multiple-quantum well is higher than the indium component in the multiple-quantum well with trench defects.

8. The epitaxial structure of claim 1, wherein the light-emitting multiple-quantum well comprises a plurality of well layers and barrier layers that alternate with each other, the well layers each being made of In_{z}Ga_{1-z}N, and the barrier layers each being made of GaN.

9. A method for preparing the epitaxial structure of the InGaN-based light-emitting diode of claim 1, comprising:
1) providing the substrate that is usable of growing gallium nitride;
2) epitaxially growing the unintentionally doped gallium nitride layer and the n-type doped gallium nitride layer sequentially on the substrate;
3) epitaxially growing the multiple-quantum well with trench defects on the n-type doped gallium nitride layer, during which high-density trenches are formed simultaneously on a surface of a multiple-quantum well by controlling growth conditions, wherein the multiple-quantum well with trench defects is made of InₓGa₁₋ₓN/GaN, where x is the indium component in the multiple-quantum well with trench defects;
4) epitaxially growing the repairment layer on the multiple-quantum well with trench defects;
5) epitaxially growing the light-emitting multiple-quantum well on the repairment layer, wherein well layers of the light-emitting multiple-quantum well each are made of In_{z}Ga_{1-z}N, where z is the indium component in the light-emitting multiple-quantum well; and the indium component z in the light-emitting multiple-quantum well is greater than the indium component x in the multiple-quantum well with trench defects; and
6) growing the p-type doped gallium nitride layer on the light-emitting multiple-quantum well, thereby obtaining the epitaxial structure of the InGaN-based light-emitting diode.

10. The method of claim 9, wherein in step 3),
the indium component x in the multiple-quantum well with trench defects satisfies 0.1≤x≤0.4;
a density of trenches formed on a surface of the multiple-quantum well with trench defects is between 1×10⁷ cm⁻² and 1×10¹⁰ cm⁻²; and
a single trench has a lateral dimension of 10 nm to 1 μm and a depth of 10 nm to 300 nm.

11. The method of claim 9, wherein in step 3), the growth conditions of the high-density trenches are: lowering growth temperatures of well layers and/or barrier layers, using trimethylgallium as a metal source, reducing a flow ratio of ammonia to the metal source, or improving a flow ratio of trimethylindium to triethylgallium.

12. The method of claim 11, wherein in step 3), the growth conditions of the high-density trenches are: growing the well layers at a temperature of 500 °C to 750 °C and the barrier layers at a temperature of 600 °C to 850 °C, the flow ratio of trimethylindium to triethylgallium ranging from 5:1 to-50:1, or the flow ratio of ammonia to the metal source ranging from 50:1 to-500:1.

13. The method of claim 9, wherein in step 4),
the repairment layer has a thickness of less than 500 nm;
the repairment layer is made of a In_{y}Ga_{1-y}N film, a In_{y}Ga_{1-y}N/GaN superlattice, or a gallium nitride layer, where y is an indium component in In_{y}Ga_{1-y}N in the repairment layer, and satisfies 0.01≤y≤0.2;
a growth temperature of the repairment layer is in a range of 750 °C to 1000 °C; and
the growth temperature of the repairment layer is higher than a growth temperature of the multiple-quantum well with trench defects.

14. The method of claim 9, wherein in step 5), the indium component z in the light-emitting multiple-quantum well satisfies 0.2≤z≤0.5.

15. The method of claim 9, wherein in step 5), for the light-emitting multiple-quantum well, growth temperatures of the well layers each are in a range of 600 °C to 750 °C, growth temperatures of the barrier layers each are in a range of 700 °C to 900 °C, triethylgallium is used as a metal source, and a flow ratio of trimethylindium to triethylgallium is in a range of 1:1-to 20:1.

16. The epitaxial structure of claim 4, wherein the multiple-quantum well with trench defects comprises a plurality of well layers and barrier layers that alternate with each other;
the well layers each are made of InₓGa₁₋ₓN, where x is the indium component in the multiple-quantum well with trench defects; and
the barrier layers each are made of GaN.

17. The epitaxial structure of claim 7, wherein the light-emitting multiple-quantum well comprises a plurality of well layers and barrier layers that alternate with each other, the well layers each being made of In_{z}Ga_{1-z}N, and the barrier layers each being made of GaN.

18. The method of claim 9, wherein the unintentionally doped gallium nitride layer has a thickness of 1 μm to 5 μm, and the n-type doped gallium nitride layer has a thickness of 1 μm to 10 μm; and
the n-type doped gallium nitride layer has a doping concentration of 1×10¹⁸ cm^{-3 to} 1×10²⁰ cm⁻³.

19. The method of claim 9, wherein the indium component in InₓGa₁₋ₓN in the multiple-quantum well with trench defects satisfies 0.1≤x≤0.4;
a density of trenches formed on a surface of the multiple-quantum well is between 1×10⁷ cm⁻² and 1×10¹⁰ cm⁻²; and
a single trench has a lateral dimension of 10 nm to 1 μm and a depth of 10 nm to 300 nm.

20. The method of claim 9, wherein the multiple-quantum well with trench defects comprises a plurality of well layers and barrier layers that alternate with each other;
the well layers each are made of InₓGa₁₋ₓN, where x is the indium component in the multiple-quantum well with trench defects; and
the barrier layers each are made of GaN.
